(19) United States
(12) Patent Application Publication
(10) Pub. No.: US 2024/0116709 A1
(43) Pub. Date: Apr. 11, 2024

(54) SUBSTRATE PROCESSING APPARATUS

(71) Applicant: Tokyo Electron Limited, Tokyo (JP)

(72) Inventors: Masato KADOBE, Fuchu City (JP); Hiromi NITADORI, Oshu City (JP); Takahiro ABE, Fuchu City (JP); Junichi SATO, Oshu City (JP)

(21) Appl. No.: 18/483,050

(22) Filed: Oct. 9, 2023

(30) Foreign Application Priority Data
Oct. 11, 2022 (JP) 2022-163281

(51) Int. Cl. B65G 1/10; B65G 49/06

(52) U.S. Cl. CPC B65G 1/10; B65G 49/061; B65G 49/062; B65G 2201/0297

(57) ABSTRACT

A substrate processing apparatus includes: a loading/unloading part having a first side surface into or from which a container accommodating a substrate is loaded or unloaded and a second side surface opposite to the first side surface; a substrate transfer part extending in a first direction orthogonal to the second side surface; and a plurality of batch processors adjacent to each other in a length direction of the substrate transfer part. The loading/unloading part includes: a first transfer device and a second transfer device configured to transfer the container; a first area accessible to the first transfer device and having a plurality of first storage shelves configured to store the container, a second area accessible to the second transfer device and having a plurality of second storage shelves configured to store the container; and a movable shelf configured to be movable between the first area and the second area.

### CROSS-REFERENCE TO RELATED APPLICATION

This application is based upon and claims the benefit of priority from Japanese Patent Application No. 2022-163281, filed on Oct. 11, 2022, the entire contents of which are incorporated herein by reference.

### TECHNICAL FIELD

The present disclosure relates to a substrate processing apparatus.

### BACKGROUND

A substrate processing apparatus that includes a loading/unloading part having a storage shelf for temporarily storing a cassette and having a cassette transfer device capable of accessing the storage shelf is known (for example, see Patent Document 1).

### PRIOR ART DOCUMENT

### Patent Document

Patent Document 1: Japanese Patent Laid-Open Publication No. 2020-113746

### SUMMARY

According to one embodiment of the present disclosure, there is provided a substrate processing apparatus including: a loading/unloading part having a first side surface into or from which a container accommodating a substrate is loaded or unloaded and a second side surface opposite to the first side surface; a substrate transfer part extending in a first direction orthogonal to the second side surface; and a plurality of batch processors adjacent to each other in a length direction of the substrate transfer part. The loading/unloading part includes: a first transfer device and a second transfer device configured to transfer the container; a first area accessible to the first transfer device and having a plurality of first storage shelves configured to store the container, a second area accessible to the second transfer device and having a plurality of second storage shelves configured to store the container; and a movable shelf configured to be movable between the first area and the second area.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a perspective view 1 illustrating a substrate processing apparatus according to an embodiment.

FIG. 2 is a perspective view 2 illustrating the substrate processing apparatus according to the embodiment.

FIG. 3 is a perspective view 3 illustrating the substrate processing apparatus according to the embodiment.

FIG. 4 is a schematic diagram 1 illustrating an example of a loading/unloading part.

FIG. 5 is a schematic diagram 2 illustrating an example of the loading/unloading part.

FIG. 6 is a side view illustrating an example of a movable unit.

FIG. 7 is a side view illustrating another example of the movable unit.

FIG. 8 is a schematic diagram 1 illustrating another example of the loading/unloading part.

FIG. 9 is a schematic diagram 2 illustrating another example of the loading/unloading part.

FIG. 10 is a schematic diagram illustrating a substrate transfer part and a batch processor.

FIG. 11 is a schematic diagram illustrating an example of a loading/unloading part of a substrate processing apparatus group according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In each of the drawings, the same or corresponding members or components are denoted by the same or corresponding reference symbols, and redundant descriptions thereof will be omitted.

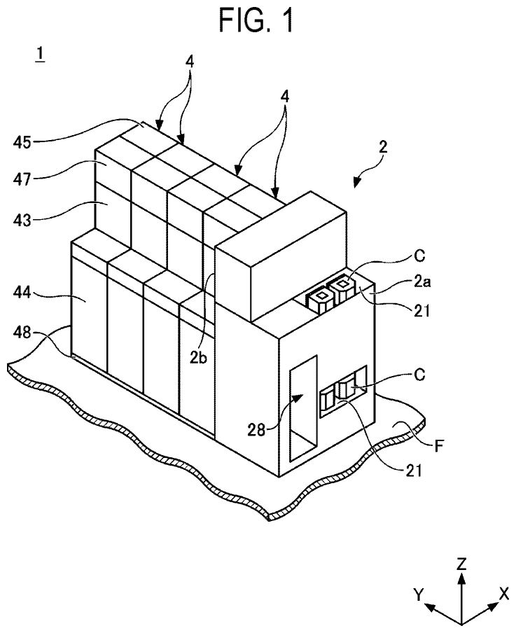

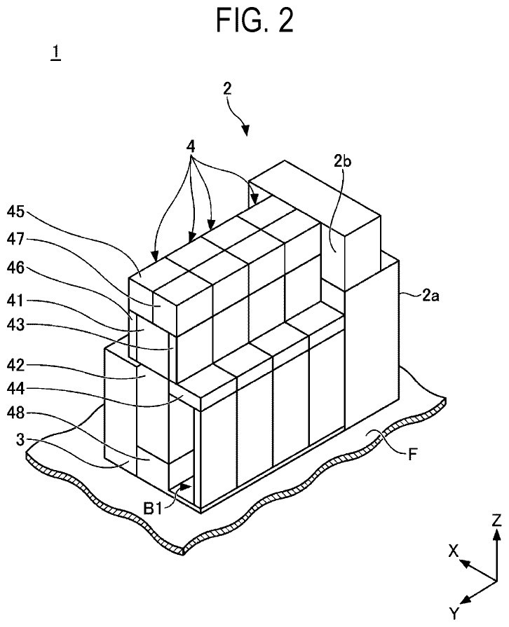

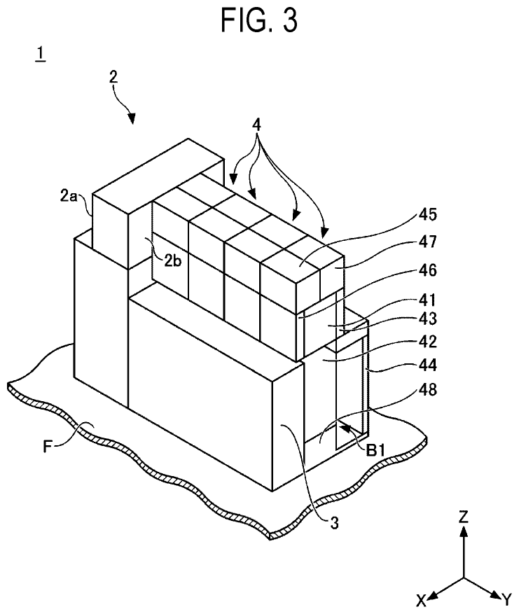

A substrate processing apparatus 1 according to an embodiment will now be described with reference to FIGS. 1 to 10. FIGS. 1 to 3 are perspective views illustrating the substrate processing apparatus 1 according to the embodiment and are views in which the substrate processing apparatus 1 is viewed from different directions, respectively.

The substrate processing apparatus 1 includes a loading/unloading part 2, a substrate transfer part 3, and a plurality of batch processors 4.

The loading/unloading part 2 has a front surface 2a into or from which a cassette C is loaded or unloaded and a rear surface 2b opposite to the front surface 2a. The front surface 2a is an example of a first side surface and is located on the negative side of the Y-axis direction of the loading/unloading part 2. The rear surface 2b is an example of a second side surface and is located on the positive side of the Y-axis direction of the loading/unloading part 2. The cassette C is a container that accommodates a plurality of (for example, 25) substrates W. The cassette C is, for example, a front-opening unified pod (FOUP). The substrates W indicate, for examples, semiconductor wafers. The inside of the loading/unloading part 2 is under, for example, an atmospheric atmosphere.

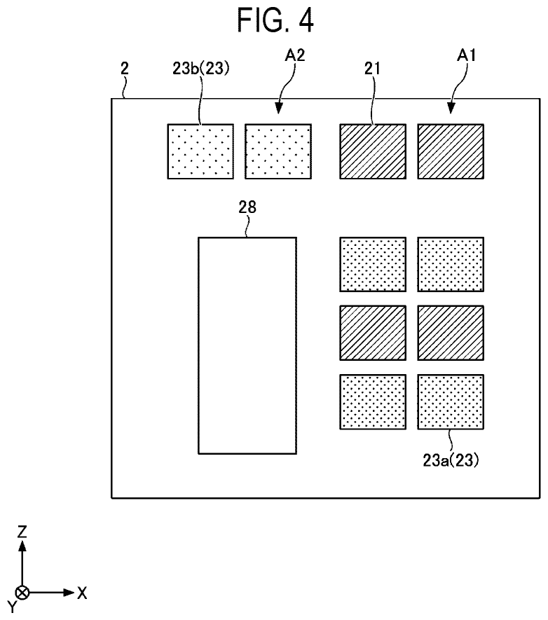

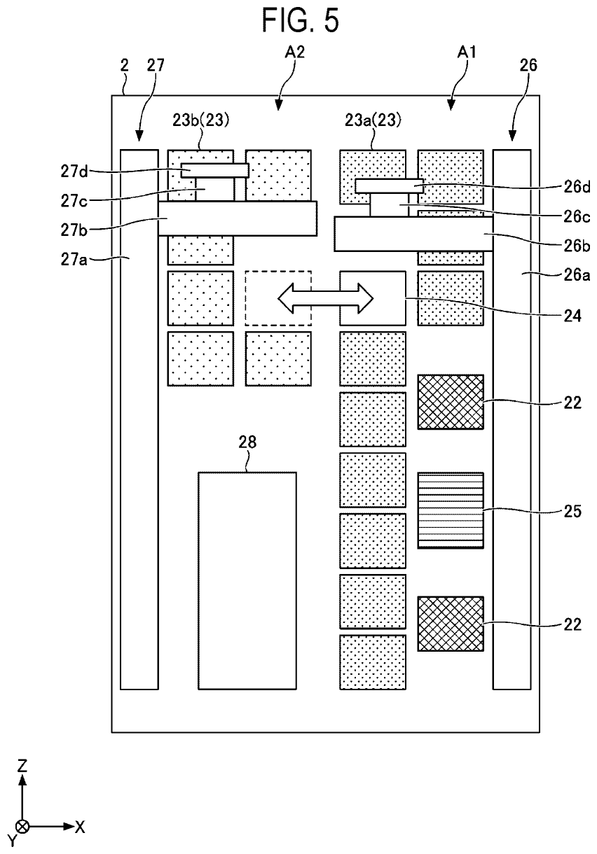

FIGS. 4 and 5 are schematic diagrams each illustrating an example of the loading/unloading part 2. FIG. 4 illustrates an area on the side of the front surface 2a of the loading/unloading part 2. FIG. 5 illustrates an area on the side of the rear surface 2b of the loading/unloading part 2.

As illustrated in FIGS. 4 and 5, the loading/unloading part 2 includes a load port 21, a front-opening interface mechanical standard (FIMS) port 22, a storage shelf 23, a movable shelf 24, and a dummy stocker 25, a first cassette transfer device 26, a second cassette transfer device 27, and a passage 28. The loading/unloading part 2 has a first area A1 and a second area A2. The first area A1 is provided on the positive side of the X-axis direction. The first area A1 is an area accessible to the first cassette transfer device 26 and inaccessible to the second cassette transfer device 27. The second area A2 is horizontally adjacent to the first area A1. The second area A2 is provided on the negative side of the X-axis direction. The second area A2 is an area accessible to the second cassette transfer device 27 and inaccessible to the first cassette transfer device 26.

The load port 21 is provided on the negative side (FIG. 4) of the Y-axis direction of the first area A1. The load port 21 is provided in two rows in the X-axis direction and in two stages in a vertical direction. A total of four load ports 21 are provided. However, the number of load ports 21 is exemplary and is not particularly limited. In the load port 21, the cassette C is transferred to and from the outside of the substrate processing apparatus 1.

The FIMS port 22 is provided on the positive side (FIG. 5) of the Y-axis direction of the first area A1. The FIMS port 22 is provided in one column in the X-axis direction and in two stages in the Z-axis direction. A total of two FIMS ports 22 are provided. However, the number of FIMS ports 22 is exemplary and is not particularly limited. The FIMS port 22 is adjacent to the substrate transfer part 3. In the FIMS port 22, the cassette C is disposed. The FIMS port 22 is provided with a cover opening/closing mechanism, which is not illustrated, for opening and closing a cover of the cassette C.

A plurality of storage shelves 23 is provided in each of the first area A1 and the second area A2. Each storage shelf 23 temporarily stores a cassette C in which a substrate W before processing is stored, a cassette C from which the substrate W is taken out so that the inside thereof is empty, and the like. The plurality of storage shelves 23 includes a plurality of first storage shelves 23a and a plurality of second storage shelves 23b.

The plurality of first storage shelves 23a is provided on the negative side of the Y-axis direction of the first area A1 (FIG. 4) and on the positive side of the Y-axis direction of the first area A1 (FIG. 5). The plurality of first storage shelves 23a is arranged side by side in a vertical direction (Z-axis direction) and a horizontal direction (X-axis direction) on each of the negative side of the Y-axis direction and the positive side of the Y-axis direction of the loading/unloading part 2. FIGS. 4 and 5 illustrate that four first storage shelves 23a are provided on the negative side of the Y-axis direction of the loading/unloading part 2 and ten first storage shelves 23a are provided on the positive side of the Y-axis direction of the loading/unloading part 2. However, the number of first storage shelves 23a is exemplary and is not particularly limited.

The plurality of second storage shelves 23b is provided on the negative side of the Y-axis direction of the second area A2 (FIG. 4) and on the positive side of the Y-axis direction of the second area A2 (FIG. 5). The plurality of second storage shelves 23b is arranged side by side in a vertical direction (Z-axis direction) and a horizontal direction (X-axis direction) on each of the negative side of the Y-axis direction and the positive side of the Y-axis direction of the loading/unloading part 2. FIGS. 4 and 5 illustrate that two second storage shelves 23b are provided on the negative side of the Y-axis direction of the loading/unloading part 2 and six second storage shelves 23b are provided on the positive side of the Y-axis direction of the loading/unloading part 2. However, the number of first storage shelves 23b is exemplary and is not particularly limited.

The movable shelf 24 is configured to be movable in the horizontal direction between the first area A1 and the second area A2. The movable shelf 24 is provided, for example, on the positive side of the Y-axis direction of the loading/unloading part 2. The movable shelf 24 may be provided on the negative side of the Y-axis direction of the loading/unloading part 2. The movable shelf 24 may be provided on both the positive side of the Y-axis direction and the negative side of the Y-axis direction of the loading/unloading part 2. The movable shelf 24 is movable in the horizontal direction (X-axis direction).

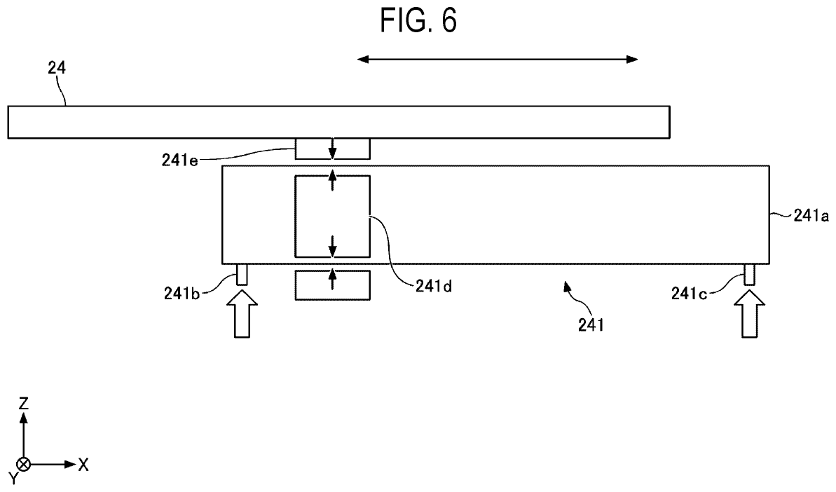

FIG. 6 is a side view illustrating an example of a movable unit. As illustrated in FIG. 6, the movable shelf 24 may be movable in the horizontal direction by the power of a rodless cylinder 241. The rodless cylinder 241 is an example of a driver. The rodless cylinder 241 includes a cylinder 241a, air supply ports 241b and 241c, an internal movable part 241d, and an external movable part 241e. The air supply ports 241b and 241c are configured to be capable of supplying air to the inside of the cylinder 241a. The air supply port 241b is provided at one end of the cylinder 241a. The air supply port 241c is provided at the other end of the cylinder 241a. The internal movable part 241d is configured to be movable inside the cylinder 241a. The external movable part 241e is provided outside the cylinder 241a. The external movable part 241e is configured to be movable integrally with the internal movable part 241d by magnetic attraction force. The movable shelf 24 is fixed to the external movable part 241e. When air is supplied from the air supply port 241b to the inside of the cylinder 241a, the internal movable part 241d, the external movable part 241e, and the movable shelf 24 move integrally towards the positive side of the X-axis direction. When air is supplied from the air supply port 241c to the inside of the cylinder 241a, the internal movable part 241d, the external movable part 241e, and the movable shelf 24 move integrally towards the negative side of the X-axis direction. Since an area occupied by the driver may be reduced using the rodless cylinder 241, the number of storage shelves 23 provided in the loading/unloading part 2 may be increased.

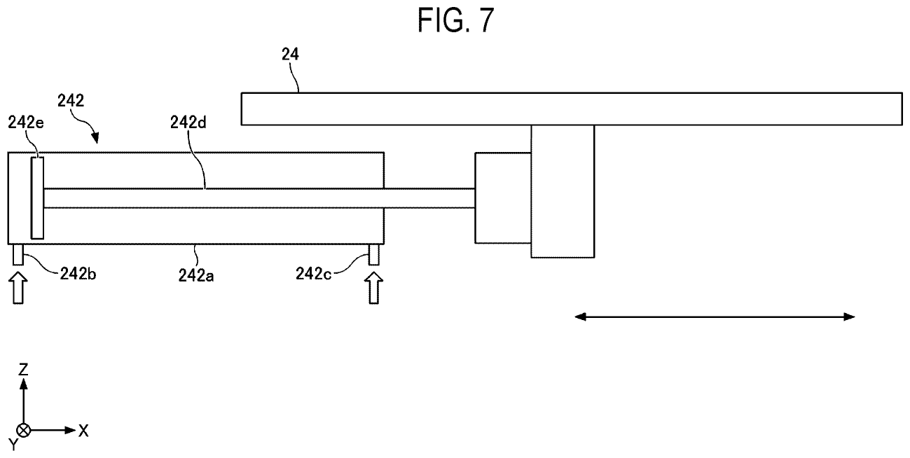

FIG. 7 is a side view illustrating another example of the movable unit. As illustrated in FIG. 7, the movable shelf 24 may be movable in the horizontal direction by the power of a rod-provided cylinder 242. The rod-provided cylinder 242 is an example of the driver. The rod-provided cylinder 242 includes a cylinder 242a, air supply ports 242b and 242c, a rod 242d, and a piston 242e. The air supply ports 242b and 242c are configured to be capable of supplying air to the inside of the cylinder 242a. The air supply port 242b is provided at one end of the cylinder 242a. The air supply port 242c is provided at the other end of the cylinder 242a. The rod 242d is configured to be movable in an axis direction of the cylinder 242a. The piston 242e is fixed to an end of the rod 242d. The movable shelf 24 is fixed to the other end of the rod 242d. When air is supplied from the air supply port 242b to the inside of the cylinder 242a, the rod 242d, the piston 242e, and the movable shelf 24 move integrally towards the positive side of the X-axis direction. When air is supplied from the air supply port 242c to the inside of the cylinder 242a, the rod 242d, the piston 242e, and the movable shelf 24 move integrally towards the negative side of the X-axis direction.

The driver is not limited to the rodless cylinder 241 and the rod-provided cylinder 242. For example, the driver may be a linear motor, a combination of a rotary motor and a ball screw, or a combination of the rotary motor and a rack pinion.

The dummy stocker 25 is provided on the positive side of the Y-axis direction of the first area A1 (FIG. 5). One dummy stocker 25 is provided. However, the number of dummy stockers 25 is exemplary and is not particularly limited. The dummy stocker 25 is adjacent to the substrate transfer part 3. The inside of the dummy stocker 25 communicates with the inside of the substrate transfer part 3. The inside of the dummy stocker 25 is under an inert gas atmosphere, for example, a nitrogen gas atmosphere. The dummy stocker 25 is accessible to a substrate transfer device 31, which will be described later, provided in the substrate transfer part 3. A plurality of (for example, 40) dummy substrates is accommodated in the dummy stocker 25. The dummy substrates are loaded in the inside of the dummy stocker 25 and unloaded from the dummy stocker 25, by the substrate transfer device 31, which will be described later, provided in the substrate transfer part 3.

The first cassette transfer device 26 is an example of a first transfer device and is configured to be capable of accessing the first area A1. The first cassette transfer device 26 is configured to be capable of transferring the cassette C between the load port 21, the FINIS port 22, the first storage shelf 23a, and the movable shelf 24. The first cassette transfer device 26 is configured to be movable in the vertical direction (Z-axis direction) and horizontal directions (X-axis direction and Y-axis direction).

The first cassette transfer device 26 includes a first guide 26a, a second guide 26b, a moving part 26c, and a holder 26d. The first guide 26a extends in the vertical direction (Z-axis direction). The second guide 26b moves in the vertical direction while being guided to the first guide 26a. The second guide 26b extends in the horizontal direction (X-axis direction). The moving part 26c moves in the horizontal direction (X-axis direction) while being guided to the second guide 26b. The holder 26d is installed at the moving part 26c. The holder 26d moves the cassette C in the horizontal direction (Y-axis direction) in a state of holding and supporting the cassette C.

The first cassette transfer device 26 is incapable of accessing, for example, the second area A2. In this case, since an operating range in the horizontal direction (X-axis direction) of the first cassette transfer device 26 may be narrowed, the first cassette transfer device 26 may be suppressed from being enlarged. For example, since the length of the horizontal direction (X-axis direction) of the second guide 26b may be shortened, deterioration of transfer position accuracy due to bending of the second guide 26b may be suppressed.

The second cassette transfer device 27 is an example of a second transfer device and is configured to be capable of accessing the second area A2. The second cassette transfer device 27 is configured to be capable of transferring the cassette C between the second storage shelf 23b and the movable shelf 24. The second cassette transfer device 27 is configured to be movable in the vertical direction (Z-axis direction) and horizontal directions (X-axis direction and Y-axis direction).

The second cassette transfer device 27 includes a first guide 27a, a second guide 27b, a moving part 27c, and a holder 27d. The first guide 27a extends in the vertical direction (Z-axis direction). The second guide 27b moves in the vertical direction while being guided to the first guide 27a. The second guide 27b extends in the horizontal direction (X-axis direction). The moving part 27c moves in the horizontal direction (X-axis direction) while being guided to the second guide 27b. The holder 27d is installed at the moving part 27c. The holder 27d moves the cassette C in a horizontal direction (Y-axis direction) in a state of holding and supporting the cassette C.

The second cassette transfer device 27 is incapable of accessing, for example, the first area A1. In this case, since an operating range in the horizontal direction (X-axis direction) of the second cassette transfer device 27 may be narrowed, the second cassette transfer device 27 may be suppressed from being enlarged. For example, since the length of the horizontal direction (X-axis direction) of the second guide 27b may be shortened, deterioration of transfer position accuracy due to bending of the second guide 27b may be suppressed.

The passage 28 passes through the loading/unloading part 2 to communicate with the front surface 2a and the rear surface 2b. The passage 28 is connected to a maintenance area B1 described later. Since the passage 28 is formed, an operator may enter and exit the maintenance area B1 from the front surface 2a of the loading/unloading part 2. The passage 28 is used when performing maintenance of the batch processors 4.

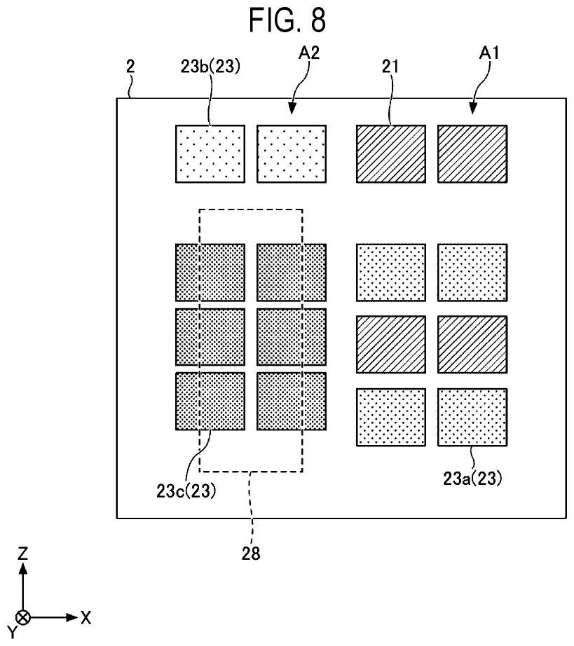

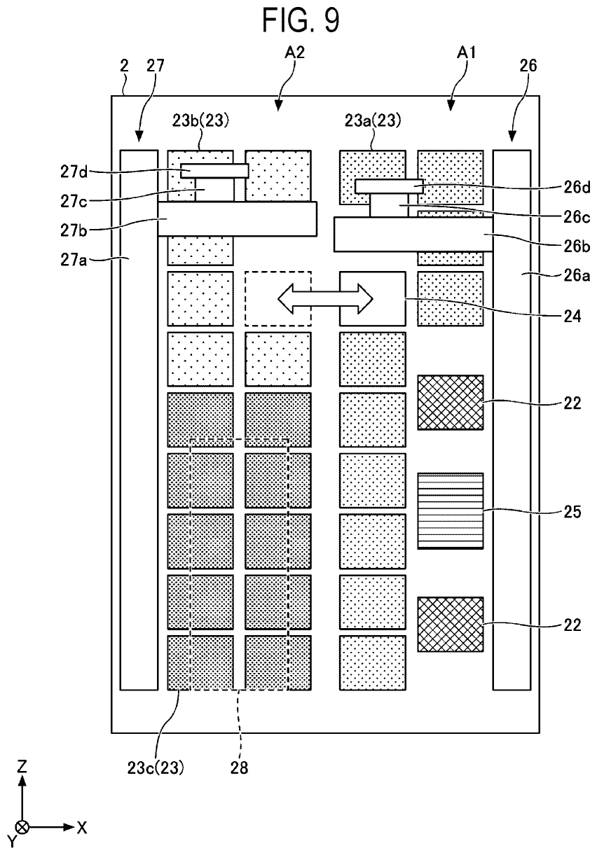

FIGS. 8 and 9 are schematic diagrams illustrating another example of the loading/unloading part. FIG. 8 illustrates an area on the side of the front surface 2a of the loading/unloading part 2. FIG. 9 illustrates an area on the side of the rear surface 2b of the loading/unloading part 2.

The loading/unloading part 2 illustrated in FIGS. 8 and 9 is different from the loading/unloading part 2 illustrated in FIGS. 4 and 5 in that the passage 28 may be formed as needed. For example, the passage 28 is formed when performing maintenance of the batch processor 4. In an area in which the passage 28 is formed, a plurality of third storage shelves 23c configured to be sprung up by a hinge, for example, is provided. The third storage shelves 23c are provided in the second area A2. The third storage shelves 23c are sprung up and then stored when the passage 28 is formed.

According to the loading/unloading part 2 illustrated in FIGS. 8 and 9, since the third storage shelves 23c may be disposed in an area in which the passage 28 is formed when the passage 28 is not used, the number of cassettes C capable of being stored may be increased when the passage 28 is not used.

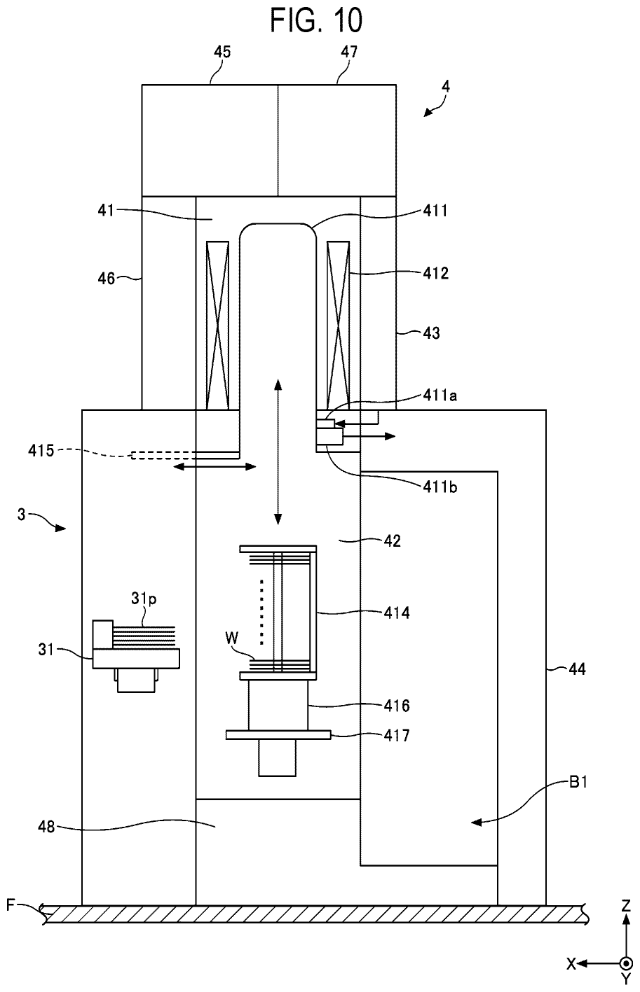

FIG. 10 is a schematic diagram illustrating the substrate transfer part 3 and the batch processor 4.

The substrate transfer part 3 is disposed on the positive side of the Y-axis direction of the loading/unloading part 2. The substrate transfer part 3 extends in a first direction (Y-axis direction) orthogonal to the rear surface 2b of the loading/unloading part 2. The substrate transfer part 3 is installed on a floor F. One substrate transfer part 3 is provided in common with respect to a plurality of batch processors 4. That is, the plurality of batch processors 4 has the substrate transfer part 3 which is common thereto. In an embodiment, the inside of the substrate transfer part 3 is under an inert gas atmosphere such as a nitrogen gas atmosphere. This may suppress oxidation of the substrate W in the substrate transfer part 3.

The substrate transfer part 3 includes a substrate transfer device 31. The substrate transfer device 31 transfers the substrate W between the loading/unloading part 2 and each of the plurality of batch processors 4. The substrate transfer device 31 has a plurality of peaks 31p. Thereby, the substrate transfer device 31 may transfer a plurality of substrates W simultaneously. For this reason, the time required to transfer the substrates W may be shortened. The number of peaks 31p is not particularly limited.

The plurality of batch processors 4 is disposed on the negative side of the X-axis direction of the substrate transfer part 3. The plurality of batch processors 4 is disposed adjacent to each other in the longitudinal direction (Y-axis direction) of the substrate transfer part 3. In the illustrated example, four batch processors 4 are disposed adjacent to each other in the longitudinal direction of the substrate transfer part 3. Each of the batch processors 4 processes the plurality of substrates W collectively. In an embodiment, the inside of each of the batch processors 4 is under an inert gas atmosphere such as a nitrogen gas atmosphere. Oxidation of the substrates W in the batch processors 4 may thereby be suppressed. Each of the batch processors 4 includes a heat treatment unit 41, a load unit 42, a gas supply unit 43, an exhaust unit 44, a process module control unit 45, and a forced air cooling unit 46, a gas control unit 47, and a floor box 48.

The heat treatment unit 41 performs predetermined heat treatment on the plurality of substrates W. The heat treatment unit 41 includes a processing container 411 and a heater 412.

The processing container 411 accommodates a substrate holder 414. The substrate holder 414 holds and supports the substrates W substantially horizontally at a predetermined interval in a vertical direction. The substrate holder 414 is made of, for example, a heat-resistant material such as quartz or silicon carbide. The processing container 411 is provided with a gas introduction port 411a and an exhaust port 411b.

The gas introduction port 411a introduces gas into the processing container 411. The gas introduction port 411a is provided on the negative side of the X-axis direction of the processing container 411.

The exhaust port 411b exhausts the gas inside the processing container 411. The exhaust port 411b is provided on the negative side of the X-axis direction of the processing container 411.

The heater 412 has, for example, a cylindrical shape and is provided around the processing container 411. The heater 412 heats the substrates W accommodated in the processing container 411. A shutter 415 is provided below the processing container 411. The shutter 415 is configured to move horizontally between a position at which an opening of a lower end of the processing container 411 is closed and a position at which the opening of the lower end of the processing container is not closed. The shutter 415 closes the opening of the lower end of the processing container 411 during a period in which the substrate holder 414 is unloaded from the processing container 411 and then the next substrate holder 414 is loaded thereinto.

The load unit 42 is provided below the heat treatment unit 41. The load unit 42 is installed on the floor F with the floor box 48 interposed therebetween. The floor box 48 may be configured to be integrated with the load unit 42 by being built thereinto. The load unit 42 transfers and receives the substrates W accommodated in the processing container 411 to and from the substrate transfer part 3. In the load unit 42, the substrate holder 414 is loaded on a cover 417 with a heat-insulating tube 416 interposed therebetween. The cover 417 is supported by a lifting mechanism, which is not illustrated. The lifting mechanism loads or unloads the substrate holder 414 into or from the processing container 411 by lifting the cover 417. The lifting mechanism includes, for example, a ball screw. The load unit 42 also functions as a space for cooling the substrates W treated in the heat treatment unit 41.

The gas supply unit 43 is disposed on the side opposite to the side on which the substrate transfer part 3 of the heat treatment unit 41 is disposed. The gas supply unit 43 supplies treatment gas to the gas introduction port 411a. The gas supply unit 43 is installed on, for example, the exhaust unit 44. The gas supply unit 43 is disposed at substantially the same height as the processing container 411, for example. The gas supply unit 43 includes a flow controller, an on/off valve, and the like.

The exhaust unit 44 is disposed on the same side as the gas supply unit 43. In one embodiment, the exhaust unit 44 is disposed at a different height from the gas supply unit 43 such as below the gas supply unit 43. The exhaust unit 44 has an inverse L-shape when viewed in a plane from a first direction (Y-axis direction). The exhaust unit 44 forms a maintenance area B1 between the load unit 42 and the exhaust unit 44. The maintenance area B1 is a maintenance area that is located at a lower place of the apparatus to allow an operator to enter and exit. The operator may easily perform maintenance of the plurality of batch processors 4 arranged in front and rear directions in the maintenance area B1.

The exhaust unit 44 has one end connected to the exhaust port 411b and the other end extending downward to pass through the floor F and connected to an exhaust device, which is not illustrated, disposed below the floor F. The exhaust device exhausts the inside of the processing container 411 via the exhaust port 411b and the exhaust unit 44 to reduce pressure. The exhaust device includes a vacuum pump, a valve, and the like.

The forced air cooling unit 46 is a unit that generates a refrigerant supplied to the heater 412 and includes a heat exchanger, a blower, a valve, and a pipe. The refrigerant may be air. The forced air cooling unit 46 is provided on the positive side of the X-axis direction of the heat treatment unit 41. The refrigerant sent from the forced air cooling unit 46 is supplied to a space between the processing container 411 and the heater 412. Thereby, the processing container 411 may be cooled in a short time.

The process module control unit 45 and the gas control unit 47 are disposed on the ceiling of the heat treatment unit 41. The process module control unit 45 and the gas control unit 47 control the operation of each part of the batch processors 4. The process module control unit 45 and the gas control unit 47 include various control devices.

In addition, the arrangement of the heat treatment unit 41, the load unit 42, the gas supply unit 43, the exhaust unit 44, the process module control unit 45, the forced air cooling unit 46, the gas control unit 47, and the floor box 48 is exemplary and is not particularly limited.

As described above, in the substrate processing apparatus 1 according to the embodiment, the loading/unloading part 2 includes the movable shelf 24 that is movable between the first area A1 accessible to the first cassette transfer device 26 and the second area A2 accessible to the second cassette transfer device 27. This may make it possible to narrow the operating range of the first cassette transfer device 26 and the second cassette transfer device 27 in the horizontal direction (X-axis direction). Thereby, the number of the cassettes C capable of being stored may be increased without enlarging the first cassette transfer device 26 and the second cassette transfer device 27.

In addition, in the substrate processing apparatus 1 according to the embodiment, since a plurality of batch processors 4 is disposed for one substrate transfer part 3, the installation area of the substrate processing apparatus 1 may be reduced as compared with the case in which one batch processor 4 is disposed for one substrate transfer part 3. Thereby, productivity per unit area is improved.

In addition, the substrate processing apparatus 1 has the maintenance area B1 formed between the load unit 42 and the exhaust unit 44. Thereby, in the maintenance area B1, an operator may easily perform maintenance of the plurality of batch processors 4 arranged in front and rear directions.

It is to be noted that the embodiments disclosed herein are exemplary in all respects and are not restrictive. The above-described embodiments may be omitted, replaced, and/or modified in various forms without departing from the scope and spirit of the appended claims.

In the above embodiments, while the case where one substrate processing apparatus 1 is disposed has been described, the present disclosure is not limited thereto. For example, a plurality of substrate processing apparatuses may be disposed in the X-axis direction to form a substrate processing apparatus group.

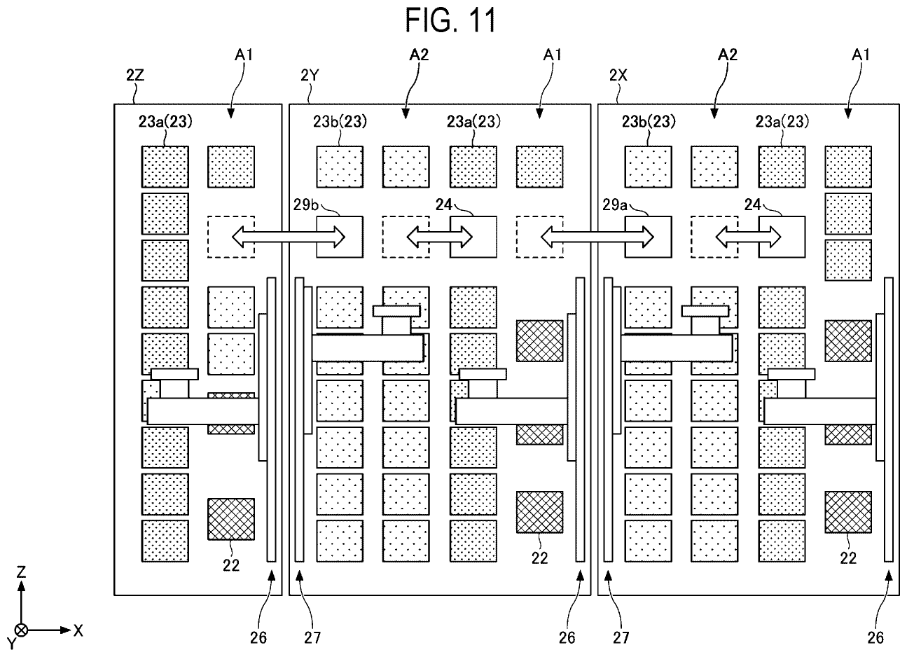

FIG. 11 is a schematic diagram illustrating an example of a loading/unloading part of a substrate processing apparatus group according to an embodiment. FIG. 11 illustrates an area on the side of the rear surface of the loading/unloading part.

In the substrate processing apparatus group in which a plurality of substrate processing apparatuses is disposed in the X-axis direction, loading/unloading parts 2X, 2Y, and 2Z are disposed in the X-axis direction, as illustrated in FIG. 11, for example. The loading/unloading part 2Y is adjacent to the loading/unloading part 2X and the loading/unloading part 2Z. In this case, a movable shelf 29a movable between a second area A2 of the loading/unloading part 2X and a first area A1 of the loading/unloading part 2Y, and a movable shelf 29b movable between a second area A2 of the loading/unloading part 2Y and a first area A1 of the loading/unloading part 2Z may be provided. Thereby, each substrate processing apparatus may transfer the cassette C between the substrate processing apparatus and a substrate processing apparatus adjacent thereto. As a result, the storage shelves 23 may be shared among the plurality of substrate processing apparatuses. In this way, a substrate processing apparatus group with high expandability is obtained. In addition, movable shelves 29a and 29b are examples of second movable shelves.

The substrate processing apparatus group may also include, for example, the substrate processing apparatus 1 provided with a plurality of batch processors 4 and a substrate processing apparatus provided with one batch processor 4. The substrate processing apparatus group may include the substrate processing apparatus 1 provided with a plurality of batch processors 4 and may not include a substrate processing apparatus provided with one batch processor 4. In this way, the substrate processing apparatus group includes at least one substrate processing apparatus 1 provided with a plurality of batch processors 4.

According to the present disclosure in some embodiments, the number of cassettes capable of being stored can be increased without enlarging the transfer device.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a loading/unloading part having a first side surface into or from which a container accommodating a substrate is loaded or unloaded and a second side surface opposite to the first side surface;
a substrate transfer part extending in a first direction orthogonal to the second side surface; and
a plurality of batch processors adjacent to each other in a length direction of the substrate transfer part,
wherein the loading/unloading part comprises:
a first transfer device and a second transfer device configured to transfer the container;
a first area accessible to the first transfer device and having a plurality of first storage shelves configured to store the container;
a second area accessible to the second transfer device and having a plurality of second storage shelves configured to store the container; and
a movable shelf configured to be movable between the first area and the second area.

2. The substrate processing apparatus of claim 1, wherein the first area and the second area are adjacent to each other in a horizontal direction, and
wherein the movable shelf is movable in the horizontal direction.

3. The substrate processing apparatus of claim 2, including a second movable shelf movable between the first area or the second area and another substrate processing apparatus provided adjacent to the substrate processing apparatus.

4. The substrate processing apparatus of claim 1, wherein the plurality of first storage shelves is arranged side by side in a vertical direction and a horizontal direction, and
wherein the plurality of second storage shelves is arranged side by side in the vertical direction and the horizontal direction.

5. The substrate processing apparatus of claim 4, including a second movable shelf movable between the first area or the second area and another substrate processing apparatus provided adjacent to the substrate processing apparatus.

6. The substrate processing apparatus of claim 1, wherein the loading/unloading part includes a third storage shelve accessible from the substrate transfer part and accommodating a dummy substrate.

7. The substrate processing apparatus of claim 6, including a second movable shelf movable between the first area or the second area and another substrate processing apparatus provided adjacent to the substrate processing apparatus.

8. The substrate processing apparatus of claim 1, wherein the loading/unloading part includes a driver configured to move the movable shelf between the first area and the second area, and
wherein the driver includes a rodless cylinder.

9. The substrate processing apparatus of claim 8, including a second movable shelf movable between the first area or the second area and another substrate processing apparatus provided adjacent to the substrate processing apparatus.

10. The substrate processing apparatus of claim 1, wherein the first transfer device is incapable of accessing the second area, and
wherein the second transfer device is incapable of accessing the first area.

11. The substrate processing apparatus of claim 10, including a second movable shelf movable between the first area or the second area and another substrate processing apparatus provided adjacent to the substrate processing apparatus.

12. The substrate processing apparatus of claim 1, including a second movable shelf movable between the first area or the second area and another substrate processing apparatus provided adjacent to the substrate processing apparatus.
